(19) United States
(12) Patent Application Publication
(10) Pub. No.: US 2022/0223352 A1
(43) Pub. Date: Jul. 14, 2022

(54) INTEGRATED DEVICE FOR SOLAR-DRIVEN WATER SPLITTING

(71) Applicant: William Marsh Rice University, Houston, TX (US)

(72) Inventors: Jun Lou, Houston, TX (US); Jia Liang, Houston, TX (US)

(73) Assignee: William Marsh Rice University, Houston, TX (US)

(21) Appl. No.: 17/647,682

(22) Filed: Jan. 11, 2022

Related U.S. Application Data
(60) Provisional application No. 63/136,054, filed on Jan. 11, 2021.

(51) Int. Cl. H01G 9/20; H01G 9/00; C25B 1/04; C25B 1/55

(52) U.S. Cl. CPC H01G 9/2077; H01G 9/2031; C25B 1/55; C25B 1/04; H01G 9/0029

(57) ABSTRACT

Described is an integrated device for solar-driven water splitting. The integrated device includes cobalt phosphide (CoP) electrodes, series-connected perovskite solar cells (PSCs) encapsulated in a polymer, and a metal film connecting the CoP electrodes with the series-connected PSCs. Also described is a method for forming an integrated device for solar-driven water splitting.

### CROSS-REFERENCE TO RELATED APPLICATIONS

The present application is a Non-Provisional application of U.S. Provisional Application No. 63/136,054, filed in the United States on Jan. 11, 2021, entitled, “Water-Splitting Module as a Source of Energy,” the entirety of which is incorporated herein by reference.

### BACKGROUND

Solar energy has been regarded as the most viable power source to meet the global energy demand. Currently, the photovoltaic (PV) cell is expected to be one of the major technologies to convert solar energy into electricity. In recent years, organic-inorganic metal halide perovskites have emerged as exceptional materials for next-generation PV technology. The solar-to-electric (STE) conversion efficiency of the perovskite solar cell (PSC) has reached to 25.2%. However, large-scale applications still require energy storage and transport devices that can effectively store solar energy.

The concept of an integrated device (or “artificial leaf”) has conventionally been proposed and considered as a way to convert solar energy into chemical fuels directly. Achieving the spontaneous evolution of fuel from integrated devices by solar-driven water splitting is a technique for renewable energy conversion. However, the widespread implementation of this method is generally hindered by the associated immature architectures and inferior performances.

Most existing conventional integrated devices are based on silicon solar cells or traditional perovskite solar cells (PSCs), both of which can be expensive. It is further noted that PSCs and catalysts in existing devices are separated. More specifically, this means the PSCs are located outside of an electrolytic tank and connected to the catalysts by external wires. Therefore, when considering scalability, it is challenging to find a suitable location to place the PSC.

Several previous integrated devices are hybrid systems combining electrocatalyst electrodes with silicon or dye-sensitized PV cells. However, because of the low open-circuit voltage, high cost for commercialization, and easy electrolyte leakage, it is difficult to deploy them in large scale.

Other integrated devices consisting of PSCs and electrocatalyst electrodes still showed some major drawbacks. For instance, the lattice structures of perovskites can be easily broken in the presence of moisture. In order to prevent degradation, most previous works kept the PSC part outside of aqueous solutions which a conductive wire connecting to the catalysts inside the solution for water electrolysis. However, with the use of wiring comes several disadvantages, including inefficient electrical connections, additional ohmic loss, and additional device packaging.

Accordingly, there exists a need for an integrated device fabricated with wireless compact design, low-cost materials, and scalable methods.

The development of this invention was funded in part by The Welch Foundation under Welch Grant No. C-1716.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

One or more embodiments of the present disclosure relate to an integrated device for solar-driven water splitting. The integrated device includes cobalt phosphide (CoP) electrodes, series-connected perovskite solar cells (PSCs) encapsulated in a polymer, and a metal film connecting the CoP electrodes with the series-connected PSCs.

In one aspect, the series-connected PSCs are carbon-based.

In another aspect, each CoP electrode includes a fluorine-doped tin oxide (FTO) coated glass layer and a layer of CoP nanorod arrays on the FTO coated glass layer.

In another aspect, each PSC includes a FTO coated glass layer, layers of compact titanium dioxide (c-TiO₂) and mesoporous titanium dioxide (m-TiO₂) on the FTO coated glass layer, a perovskite layer on the layers of c-TiO₂ and m-TiO₂, and a carbon electrode layer on the perovskite layer.

In yet another aspect, a counter electrode of the series-connected PSCs is connected with an anode of the CoP electrodes by a layer of non-noble metal film, and a photoanode of the plurality of series-connected PSCs is connected with a cathode of the plurality of CoP electrodes by a layer of non-noble metal film.

One or more embodiments of the present disclosure also relate to a method for forming an integrated device for solar-driven water splitting including forming cobalt phosphide (CoP) electrodes, forming series-connected perovskite solar cells (PSCs), encapsulating the series-connected PSCs with a polymer, and connecting the CoP electrodes with the series-connected PSCs with a metal film.

In another aspect, the method further includes preparing each CoP electrode by growing cobalt-precursor (Co-pre) nanorod arrays directly on glass coated with fluorine-doped tin oxide (FTO) by a hydrothermal process, annealing the Co-pre nanorod arrays to obtain Co₃O₄ nanorod arrays, and synthesizing CoP nanorod arrays via a phosphorization treatment.

In another aspect, the method further includes preparing each PSC by depositing a layer of compact titanium dioxide (c-TiO₂) on glass coated with FTO, depositing a layer of mesoporous titanium dioxide (m-TiO₂) on the c-TiO₂ layer followed by annealing, depositing a perovskite layer on the layers of c-TiO₂ and m-TiO₂ followed by annealing, and depositing a carbon electrode layer on the perovskite layer followed by heating.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1A illustrates a schematic structure of an integrated device with the structure of two cobalt phosphide (CoP) electrodes, Surlyn, and two series-connected perovskite solar cells (PSCs) according to some embodiments of the present disclosure;

FIG. 1B illustrates a cross-sectional scanning electron microscope (SEM) image of a CoP electrode comprising glass, fluorine-doped tin oxide (FTO), and CoP nanorod according to some embodiments of the present disclosure;

FIG. 1C illustrates a cross-sectional SEM image of a PSC comprising glass, FTO, perovskite, and carbon according to some embodiments of the present disclosure;

FIG. 2 illustrates a synthesis process of CoP nanorods on FTO glass according to some embodiments of the present disclosure;

FIG. 3A illustrates polarization curves of Co-pre, Co₃O₄, and CoP nanorods in 1 molar (M) potassium hydroxide (KOH) for oxygen evolution reaction (OER) according to some embodiments of the present disclosure;

FIG. 3B illustrates Tafel slopes of Co-pre, Co₃O₄, and CoP nanorods in 1 M KOH for OER according to some embodiments of the present disclosure;

FIG. 3C illustrates polarization curves of Co-pre, Co₃O₄, and CoP nanorods in 1 M KOH for hydrogen evolution reaction (HER) according to some embodiments of the present disclosure;

FIG. 3D illustrates Tafel slopes of Co-pre, Co₃O₄, and CoP nanorods in 1 M KOH for HER according to some embodiments of the present disclosure;

FIG. 3E illustrates a polarization curve for overall water splitting of CoP catalysts in a two-electrode configuration according to some embodiments of the present disclosure;

FIG. 3F illustrates current densities of CoP catalysts as a function of reaction time at the corresponding fixed overpotentials for OER, HER, and overall water splitting according to some embodiments of the present disclosure;

FIG. 4 is a flow diagram illustrating preparing the PSC according to some embodiments of the present disclosure; and

FIG. 5 is a flow diagram illustrating forming an integrated device according to some embodiments of the present disclosure.

### DETAILED DESCRIPTION

Specific embodiments of the disclosure will now be described in detail with reference to the accompanying figures. Like elements in the various figures are denoted by like reference numerals for consistency.

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

One or more embodiments of this disclosure relate to a unique integrated device (or “artificial leaf”) to convert solar energy into chemical fuels directly. The integrated device consists of a photovoltaic (PV) cell and two or more electrocatalyst electrodes, which produce molecular hydrogen and oxygen using only sunlight and water as catalysts. In one or more embodiments, the integrated device described herein is a combination of two cobalt phosphide (CoP) electrodes and two series-connected perovskite solar cells (PSCs), which are prepared via low-cost solution processable fabrication methods. The integrated device further includes a simple encapsulation technique using Surlyn film to protect the perovskite layer. Surlyn is an extremely strong, high clarity, durable thermosetting, or thermoplastic, polymer film made from the DuPont Surlyn resin. The Surlyn film allows the integrated device to be immersed into an aqueous solution directly for solar-driven water splitting. Specifically, the integrated device described herein can be immersed into an aqueous solution directly for solar-driven water splitting to obtain chemical fuels of oxygen and hydrogen. In another embodiment, for further stability, the Surlyn film and an epoxy resin can be used together to protect the PV cell component from water. Benefitting from the wireless design, the integrated device has a compact architecture and well-connected circuits. By eliminating expensive organic hole-transporting materials (HTMs) and noble metal electrodes, the two series-connected carbon-based PSCs drove efficient, bifunctional, and earth-abundant two CoP catalyst electrodes and revealed a solar-to-hydrogen efficiency of as high as 6.7%.

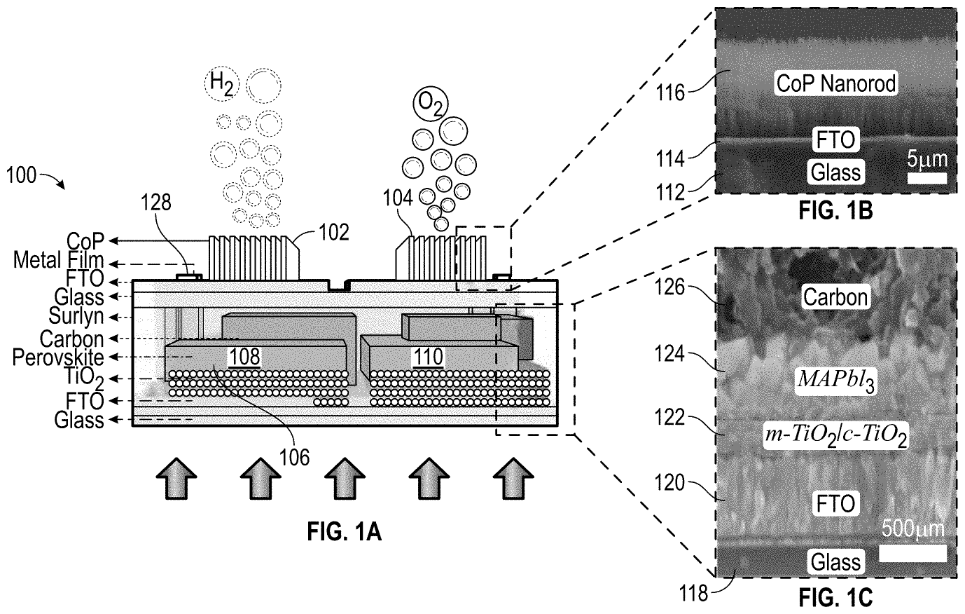

Referring now to FIGS. 1A-1C, FIG. 1A depicts the integrated device 100 having a structure of two CoP electrodes 102 (the CoP cathode) and 104 (the CoP anode), Surlyn 106, and two series-connected PSCs 108 and 110. A top part of the integrated device consists of the two CoP electrodes 102 and 104, which are fabricated by hydrothermal and phosphating methods. FIG. 1B shows a magnified view of the structure of a CoP electrode 104, depicting a structure comprising glass 112, fluorine-doped tin oxide (FTO) 114, and CoP nanorod 116. The FTO 114 under PSC 108 functions as the photoanode, and the carbon on top of PSC 110 functions as the counter electrode.

Referring again to FIG. 1A, the bottom part of the integrated device 100 consists of the two PSCs 108 and 110 connected in series. FIG. 1C shows a magnified view of the structure of a PSC 110 comprising a structure of glass 118, FTO 120, TiO₂ 122, perovskite 124, and carbon 126. As illustrated in FIG. 1C, layers of compact titanium dioxide (c-TiO₂) and mesoporous titanium dioxide (m-TiO₂) 122, and CH₃NH₃PbI₃ perovskite 124 are sequentially deposited from a precursor solution on top of the patterned FTO substrate 120, followed by doctor blading a layer of carbon electrode 126. As would be understood by one skilled in the art, doctor blading refers to a thin-film fabrication technique, which involves either running a blade over a substrate or moving a substrate underneath a blade.

In order to get an individual device, the low-cost Surlyn film 106 is used to connect the two parts and sandwich the perovskite layer 124 between them. Finally, metal films 128, comprised of, for instance, copper, gold, and/or carbon, are deposited to connect a CoP cathode (hydrogen evolution reaction (HER)) with a photoanode in the PSC part, as well as CoP anode (oxygen evolution reaction (OER)) with a counter electrode in the PSC part, respectively, as water splitting contains the two reactions: OER and HER.

As prepared, the integrated device 100 shown in FIG. 1A includes several important and distinguishing features. First, the integrated device 100 is a real integrated device and can be immersed into an aqueous solution for water splitting directly. Second, all the components in the integrated device 100 are inexpensive, earth abundant, and easy-to-fabricate. Lastly, as evidenced by experimental studies, the present invention provides a feasible method to fabricate devices, which can be extended to other photoelectrochemical devices with different material combinations.

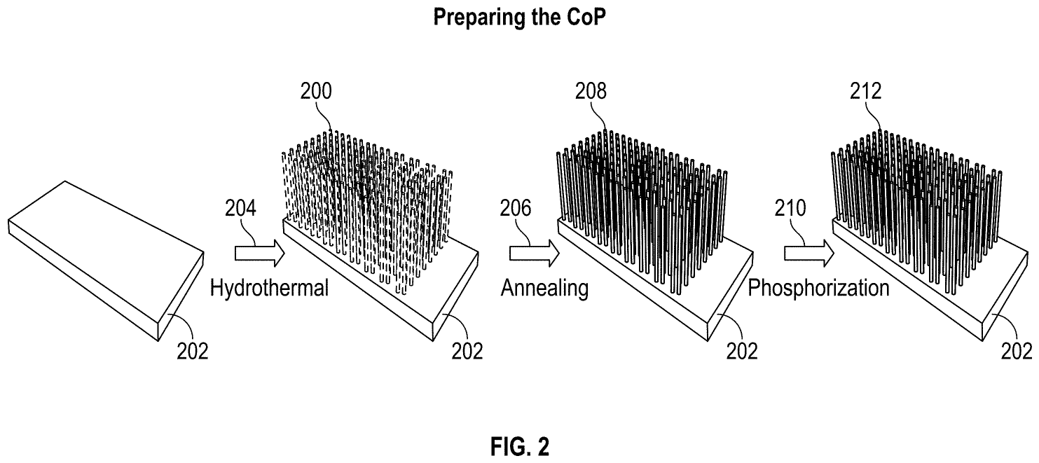

FIG. 2 shows the procedure for preparing a CoP electrode according to embodiments of the present disclosure. Cobalt-precursor (Co-pre) nanorod arrays 200 are first grown directly on a glass coated with FTO substrate 202 by a facile hydrothermal process 204. Subsequently, by annealing 206 the as-obtained Co-pre nanorod arrays at 300° C. in air, Co₃O₄ nanorod arrays 208 are obtained. Finally, targeted CoP nanorod arrays 210 (i.e., the intended final products) are synthesized by a simple phosphorization treatment 212, as described in further detail below.

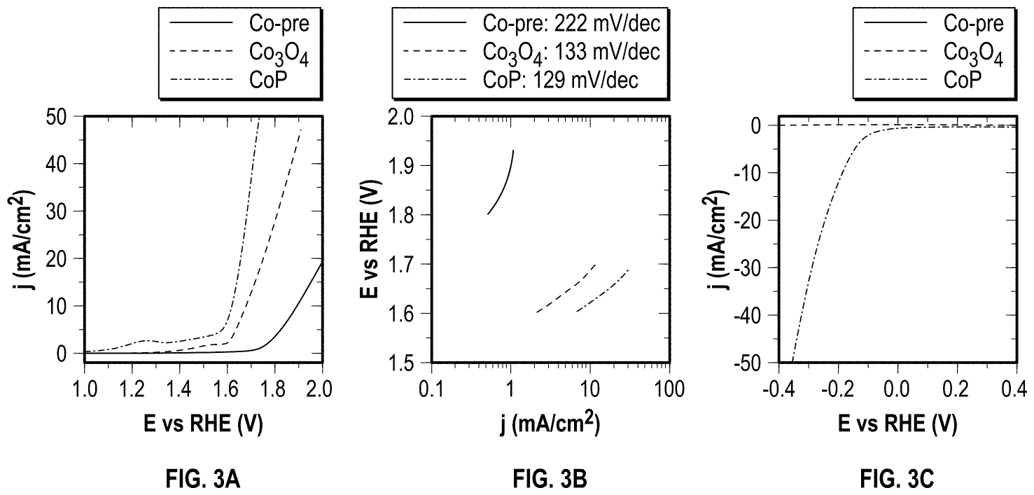

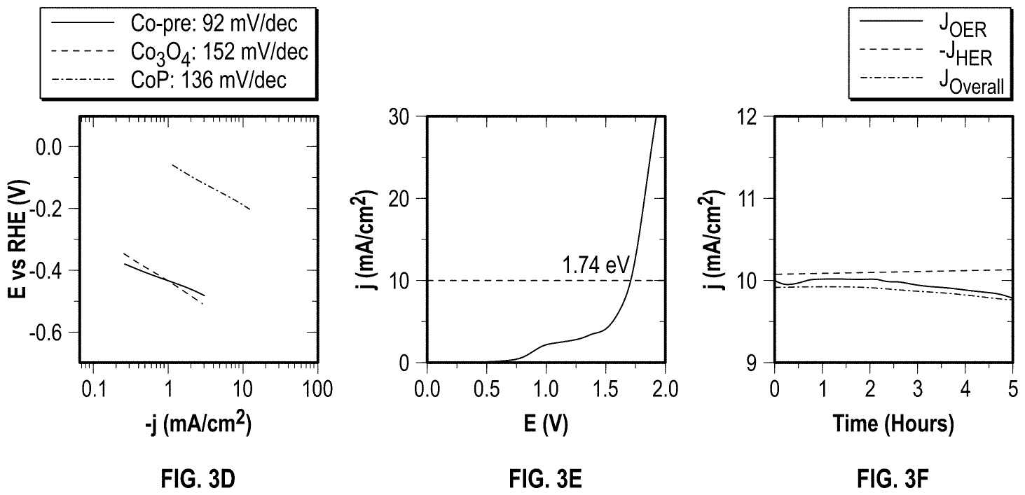

FIGS. 3A-3F illustrate performance of electric-driven OER, HER, and overall water splitting. FIG. 3A depicts polarization curves in 1 molar (M) potassium hydroxide (KOH) for OER, and FIG. 3B depicts Tafel slopes of Co-pre, Co₃O₄, and CoP nanorods in 1 M KOH for OER. FIG. 3C shows polarization curves in 1 M KOH for HER, and FIG. 3D illustrates Tafel slopes of Co-pre, Co₃O₄, and CoP nanorods in 1 M KOH for HER. FIG. 3E depicts a polarization curve for overall water splitting of CoP catalysts in a two-electrode configuration. FIG. 3F illustrates the current densities of CoP catalysts as a function of reaction time at the corresponding fixed overpotentials for OER, HER, and overall water splitting. The results indicate that the CoP nanorods can serve as a bifunctional electrocatalyst for overall water splitting with superior activity and stability.

(1) Preparation of Co-Pre, Co₃O₄, and CoP Nanorod Catalysts

In one or more embodiments, the CoP nanorod catalyst is prepared. First, the FTO glass (between two to five micrometers (μm) in width) is etched by Zinc (Zn) powder and 2.0 molar (M) hydrochloride (HCl) for desirable patterns and then sequentially cleaned with acetone, deionized water, and 2-propanol under ultrasonication and dried in air. The FTO glass is placed into a 50 milliliter (mL) Teflon-lined stainless-steel autoclave filled with 30 mL homogeneous solution containing 2 millimoles (mmol) Co(NO₃)₂.6H₂O, 8 mmol NH₄F, and 10 mmol urea. An autoclave is heated to a temperature between 120° C. and 150° C., preferably 120° C., in an electric oven and then rapidly cooled down to room temperature by water flushing. The electrode is then washed with deionized water and ethanol several times. At this point, the Co-pre catalyst on FTO glass is achieved. Then, the FTO glass with Co-pre catalyst is annealed in air at 300° C. (or any temperature between 250° C. to 350° C.) for 3 hours (h) (or any time between 2 to 5 h) to obtain a Co₃O₄ catalyst. Finally, the FTO glass with Co₃O₄ catalyst and 100 milligrams (mg) NaH₂PO₂ may be placed at two separate positions in a tube furnace with NaH₂PO₂ at the upstream side of the furnace. The furnace is heated to 300° C. for 3 h with a heating speed of 2° C. per minute. After the reaction is complete, the CoP catalyst is also on the FTO glass.

(2) Preparation of Carbon-Based Perovskite Solar Cells (PSCs)

Another embodiment includes the preparation of carbon-based two series-connected perovskite solar cells (PSCs). To achieve integrated devices for solar-driven water splitting, carbon based two-series connected PSCs with the structure of FTO glass/c-TiO₂/m-TiO₂/CH₃NH₃PbI₃/carbon are fabricated, as illustrated in FIG. 1C and described in detail below. Compared with the traditional PSCs with organic HTMs and noble-metal electrodes, the carbon-based PSCs described herein decrease the cost dramatically.

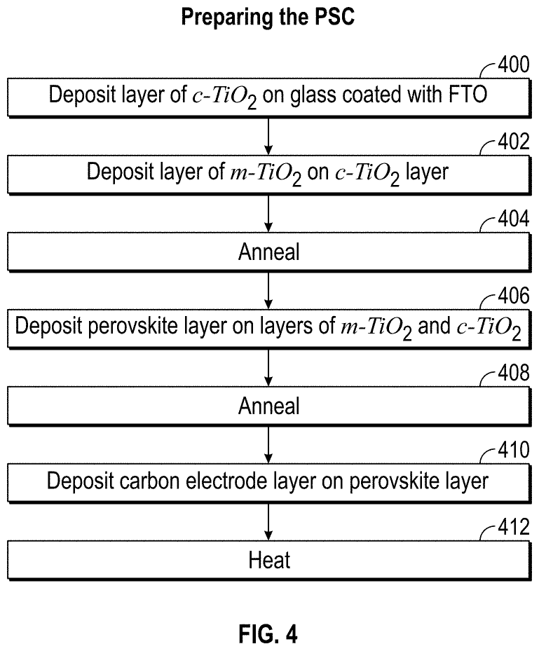

The main steps involved in preparation of the PSC according to one or more embodiments of the present disclosure are illustrated in the flow diagram of FIG. 4. First, a layer of compact titanium dioxide (c-TiO₂) is deposited on glass coated with fluorine-doped tin oxide (FTO) 400. Then, a layer of mesoporous titanium dioxide (m-TiO₂) is deposited on the c-TiO₂ layer 402 followed by annealing 404. Subsequently, a perovskite layer is deposited on the layers of c-TiO₂ and m-TiO₂ 406 followed by another annealing process 408. Finally, a carbon electrode layer is deposited on the perovskite layer 410 followed by heating 412. A more detailed description of preparation of the PSC is provided below.

The FTO glass is first etched by Zn powder and 2.0 M HCl for desirable patterns (e.g., middle and one of the edges) and then sequentially cleaned with acetone, deionized water, and 2-propanol under ultrasonication and dried in air. The c-TiO₂ layer is deposited on FTO glass by spin-coating a solution of titanium isopropoxide (0.5 M) and diethanol amine (0.5 M) at 7000 revolutions per minute (rpm) for 30 seconds (s) and followed by annealing in air at 500° C. for 2 h. The m-TiO₂ layer is then deposited by spin-coating diluted TiO₂ paste at 5000 rpm for 30 s and annealed in air at 500° C. for 30 min. Then, the substrate is immersed in an aqueous solution of 0.04 M TiCl₄ at 70° C. for 30 minutes (min), cleaned with water and 2-propanol, and then annealed at 450° C. for another 30 min. After depositing the electron transport layer, the perovskite layer is deposited by a one-step spin coating method. Specifically, the perovskite layer is formed by spin-coating (2500 rpm for 25 s) a perovskite solution prepared by dissolving 1.0 M PbI₂ and 1.0 M CH₃NH₃I in anhydrous DMF and DMSO (volume ratio 9:1). The film is then annealed at 100° C. for 45 min. Finally, the carbon electrode is deposited on the perovskite layer by doctor-blade method and then heated at 70° C. for 60 min.

(3) Preparation of Integrated Devices Combining PSCs and CoP Nanorod Catalyst Electrode

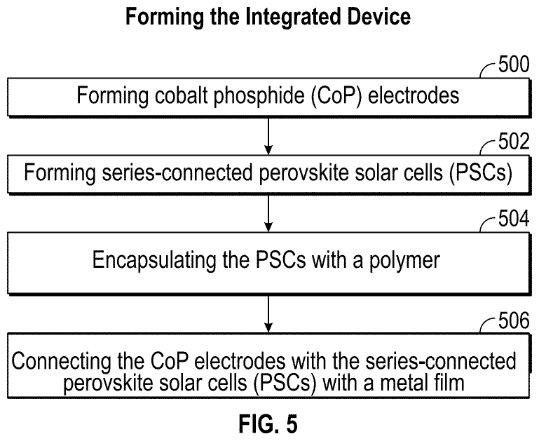

The main steps involved in preparation of the integrated device according to one or more embodiments of the present disclosure are illustrated in the flow diagram of FIG. 5. The CoP electrodes are formed 500, as described in detail above and depicted in FIG. 2. The series-connected PSCs are formed 502, as described in detail above. The PSCs are then encapsulated with a polymer 504, a non-limiting example of which includes Surlyn film. Finally, the CoP electrodes are connected with the series-connected PSC using a metal film 506.

Specifically, to integrate a PSC with a CoP electrode in one or more embodiments, a patterned Surlyn film is placed between the PSC and the CoP electrode. Then, the whole device is heated at 150-200° C. for several seconds. Following the heating step, a counter electrode of the PSC (carbon) is connected with the CoP electrode by depositing a layer of non-noble metal film. The integrated device for solar-driven HER possesses the same procedure with the integrated device for solar-driven OER. The only difference is connecting a photoanode of the PSC with CoP electrode by a layer of non-noble metal film.

For the integrated device for solar-driven water splitting, two series-connected PSCs are needed to integrate with two CoP electrodes. Specifically, a patterned Surlyn film is placed between the PSC part and the CoP electrodes, and the device is heated at 150-200° C. for several seconds. In one embodiment, the Surlyn film is cut into a first rectangle, and a second rectangle that is smaller than the first rectangle is cut and removed from a center portion of the first rectangle. Following the heating step, a counter electrode (carbon) and photoanode of the two series-connected PSCs is connected with the anode and cathode CoP electrodes by depositing a layer of non-noble metal film, respectively.

Integrated devices prepared in accordance with one or more embodiments of the present disclosure were further tested. To achieve the solar-driven overall water splitting of the integrated device, the photoanode and carbon electrode of the PSC part are connected with the patterned CoP nanorods electrodes (i.e., area of CoP cut to a desired size (e.g., 3 millimeters by 3 millimeter), as described above. The use of carbon and CoP catalyst to replace the expensive conventional components in the PSC and catalytic portions, respectively, is provided to decrease cost. Although all conventional components in this integrated device are eliminated, the two series-connected carbon-based PSCs are capable of exhibiting a high solar-to-electric conversion efficiency of 10.6%. Higher efficiencies may be reached by optimizing the PSC by composition engineering, interface engineering, and so on.

Additionally, the integrated devices display a solar-to-hydrogen efficiency that reaches as high as 6.7%. The integrated device, according to one or more embodiments, serves as a model architecture toward the future development and optimization of integrated devices that can be immersed into an aqueous solution directly for application in water splitting. Higher device efficiencies may be obtained by using higher efficiency PSCs and catalysts. Further, the encapsulation method in this invention may be changed to improve upon the device stability. For example, epoxy resins may be combined to protect the PV cell part from water.

The invention described herein provides several advantages over existing devices. These advantages may include, but are not limited to the following. The preparation method of CoP catalysts is simplified and inexpensive. The integrated device of one or more embodiments of the present disclosure can be prepared by combining PSCs and CoP nanorod catalyst electrode. Low-cost carbon materials are employed to replace the expensive materials in traditional PSCs and developed carbon-based PSCs. This integrated device can be immersed into the aqueous solution for solar-driven water splitting directly and as such, may scale-up more readily.

The achieved product of the water-splitting integrated device may produce (1) hydrogen that can be used to produce ammonia with N₂ by the Haber-Bosch process, which is used to supply the majority of the protein consumed by humans. Hydrogen is also commonly used in power stations as a coolant in generators due to its low density, low viscosity, and highest specific heat and thermal conductivity. If one connects the collected gas with a fuel cell, the fuel cell may be used to provide the electricity using the chemical fuel of oxygen and hydrogen. Additionally, hydrogen can also be used in metal refining, chemical production, heating process and so on.

Moreover, for any kind of the electrochemical reaction, such as water splitting (including oxygen evolution reaction (OER) and hydrogen evolution reaction (HER)), nitrogen reduction reaction (NRR), and carbon dioxide reduction reaction (CRR), a power source is required. Therefore, when considering how to scale the devices in the market, one must further consider the additional stress that may be imposed on existing electrical grids. Due to the abundance of solar resources, the integrated device of the present disclosure, which employs solar cells to provide electricity, can deliver energy to these reactions on demand. Fortunately, in addition to achieving water splitting using this integrated device, this integrated device can also achieve other electrochemical reactions. For example, by replacing the CoP catalyst with effective catalysts for NRR, such as MoS₂, the integrated device according to one or more embodiments of this disclosure can also achieve the electrochemical reaction of NRR. That is, the integrated device can produce ammonia using dinitrogen gas in the air as a precursor. Another example includes replacing the CoP catalyst with Cu-derived catalysts to achieve the reaction of CRR such that the integrated device can generate C₂₊ products, like C₂H₄ and C₂H₅OH, using CO₂ as a precursor.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f) for any limitations of any of the claims herein, except for those in which the claim expressly uses the words ‘means for’ together with an associated function.

What is claimed:

1. An integrated device for solar-driven water splitting, comprising:
a plurality of cobalt phosphide (CoP) electrodes;
a plurality of series-connected perovskite solar cells (PSCs); and
a metal film to connect the plurality of CoP electrodes with the plurality of series-connected PSCs,
wherein the PSCs are encapsulated by a polymer.

2. The integrated device according to claim 1, wherein the polymer is a thermosetting or a thermoplastic polymer.

3. The integrated device according to claim 1, wherein the plurality of series-connected PSCs are carbon-based.

4. The integrated device according to claim 1, wherein each CoP electrode comprises:
a fluorine-doped tin oxide (FTO) coated glass layer; and
a layer of CoP nanorod arrays on the FTO coated glass layer.

5. The integrated device according to claim 1, wherein each PSC comprises:
a fluorine-doped tin oxide (FTO) coated glass layer;
a plurality of layers of compact titanium dioxide (c-TiO₂) and mesoporous titanium dioxide (m-TiO₂) on the FTO coated glass layer;
a perovskite layer on the plurality of layers of c-TiO₂ and m-TiO₂; and
a carbon electrode layer on the perovskite layer.

6. The integrated device according to claim 1, wherein the polymer is positioned between the plurality of CoP electrodes and the plurality of series-connected PSCs.

7. The integrated device according to claim 1, wherein a counter electrode of the plurality of series-connected PSCs is connected with an anode of the plurality of CoP electrodes by a layer of non-noble metal film, and wherein a photoanode of the plurality of series-connected PSCs is connected with a cathode of the plurality of CoP electrodes by a layer of non-noble metal film.

8. A method for forming an integrated device for solar-driven water splitting, comprising acts of:
forming a plurality of cobalt phosphide (CoP) electrodes;
forming a plurality of series-connected perovskite solar cells (PSCs);
encapsulating the plurality of series-connected PSCs with a polymer; and
connecting the plurality of CoP electrodes with the plurality of series-connected PSCs with a metal film.

9. The method according to claim 8, further comprising an act of preparing each CoP electrode, wherein preparing each CoP electrode comprises acts of:
growing cobalt-precursor (Co-pre) nanorod arrays directly on glass coated with fluorine-doped tin oxide (FTO) by a hydrothermal process;
annealing the Co-pre nanorod arrays to obtain Co₃O₄ nanorod arrays; and
synthesizing CoP nanorod arrays via a phosphorization treatment.

10. The method according to claim 8, further comprising an act of preparing each PSC, wherein preparing each PSC comprises acts of:
depositing a layer of compact titanium dioxide (c-TiO₂) on glass coated with fluorine-doped tin oxide (FTO);
depositing a layer of mesoporous titanium dioxide (m-TiO₂) on the c-TiO₂ layer followed by annealing;
depositing a perovskite layer on the layers of c-TiO₂ and m-TiO₂ followed by annealing; and
depositing a carbon electrode layer on the perovskite layer followed by heating.

11. The method according to claim 8, further comprising an act of positioning the polymer is between the plurality of CoP electrodes and the plurality of series-connected PSCs.

12. The method according to claim 8, further comprising acts of:
connecting a counter electrode of the plurality of series-connected PSCs with an anode of the plurality of CoP electrodes using a layer of non-noble metal film; and
connecting a photoanode of the plurality of series-connected PSCs with a cathode of the plurality of CoP electrodes using a layer of non-noble metal film.
